(19) United States
(12) Patent Application Publication
(10) Pub. No.: US 2019/0305161 A1
(43) Pub. Date: Oct. 3, 2019

(54) THERMOPLASTIC EMBOSSED FILM

(71) Applicant: BOREALIS AG, Vienna (AT)

(72) Inventors: Francis Costa, Linz (AT); Stefan Hellstrom, Kungalv (SE)

(21) Appl. No.: 16/316,959

(22) PCT Filed: Jul. 13, 2017
(86) PCT No.: PCT/EP2017/067650

§ 371 Date: Jan. 10, 2019

(30) Foreign Application Priority Data
Jul. 15, 2016 (EP) 16179705.5

(51) Int. Cl. H01L 31/048; H01L 31/049; H01L 31/18; B32B 3/30; B32B 27/32

(52) U.S. Cl. CPC H01L 31/0481; H01L 31/049; B32B 2457/12; B32B 3/30; B32B 27/32; H01L 31/18

(57) ABSTRACT

The present invention relates to a layer element (L) comprising an ethylene polymer (a), to a multilayer assembly, preferably a photovoltaic multilayer assembly, comprising the layer element (L) of the invention, to an article comprising the layer element (L), preferably comprising a multilayer laminate comprising the layer element (L), more preferably a multilayer laminate of a photovoltaic (PV) module comprising the layer element (L) of the invention, to use of said layer element (L) for producing an article, preferably a photovoltaic module (PV), as well as to a process for producing an article, preferably a photovoltaic module, of the invention comprising the layer element (L).

The present invention relates to a layer element (L) comprising an ethylene polymer (a), to a multilayer assembly, preferably a photovoltaic multilayer assembly, comprising the layer element (L) of the invention, to an article comprising the layer element (L), preferably comprising a multilayer laminate comprising the layer element (L), more preferably a multilayer laminate of a photovoltaic (PV) module comprising the layer element (L) of the invention, to use of said layer element (L) for producing an article, preferably a photovoltaic module (PV), as well as to a process for producing an article, preferably a photovoltaic module, of the invention comprising the layer element (L).

Lamination typically using heat and pressure is a widely known technique for producing layered structures of layer elements for use in various end applications. Layer element can be a monolayer element or multilayer element produced by lamination or (co)extrusion.

Lamination is one of the steps used typically also for producing well known photovoltaic modules, also known as solar cell modules. Photovoltaic (PV) modules produce electricity from light and are used in various kind of applications as well known in the field. The type of the photovoltaic module can vary. The PV modules have typically a multilayer structure, i.e. several different layer elements which have different functions. The layer elements of the photovoltaic module can vary with respect to layer materials and layer structure. The final photovoltaic module can be rigid or flexible.

The photovoltaic (PV) module can for example contain, in a given order, a protective front layer element which can be flexible or rigid (such as a glass layer element) front encapsulation layer element, a photovoltaic element, rear encapsulation layer element, a protective back layer element, which is also called a backsheet layer element and which can be rigid or flexible; and optionally e.g. an aluminium frame.

Accordingly, part or all of the layer elements of a PV module, e.g. the encapsulation layer element, are normally of a polymeric material, like ethylene vinyl acetate (EVA) based material. In many applications, like in PV applications the layers based on EVA, need often be crosslinked during the lamination process to obtain sufficient properties to the final product. The polymer composition which is crosslinked, for instance using peroxide as a crosslinking agent, has a typical network, i.a. interpolymer crosslinks (bridges), as well known in the field. The crosslinking degree may vary depending on the end application.

The layer elements of an article, e.g. a PV module, can be arranged to a multilayer assembly which is then typically laminated in a lamination step to provide a multilayer laminate, e.g. a multilayer laminate of a final PV module. The final PV module can be further arranged e.g. to an aluminium frame for use in end application.

When laminating the multilayer assembly of a part or whole of an end article, for instance of a photovoltaic module, it needs to be ensured that no air or other gases are entrained in the final module. This can be accomplished by applying a vacuum or by applying adequate lamination pressure when laminating the photovoltaic module. However, applying a high load may damage the module lowering its lifetime or even rendering it unusable.

To accelerate the lamination cycle time the layer material should have a low melting point to shorten the heating/cooling time required. Moreover, the material should achieve the required properties without the need of crosslinking which increases the production time. Moreover, crosslinking usually leads to low molecular byproducts which may be detrimental to the lifetime of the photovoltaic module and removal thereof is cumbersome and time-consuming, e.g. requires prolonged evacuation time.

U.S. Pat. No. 7,851,694 describes a prelaminate assembly comprising a solar cell(s) and a layer element (mono- or multilayer element) wherein at least one layer consists essentially of a copolymer of alpha-olefin with alpha,beta-ethylenically unsaturated carboxylic acid comonomer(s), inonomers derivated therefrom and combinations thereof. The surface of said layer is embossed with a specific pattern of channels. It is stated that the invention results in e.g. less dirt accumulation, lower haze and use of higher efficiency de-airing and with less energy needed during lamination.

There is a continuous need to provide layer elements which improve the lamination process and the quality of the obtained multilayer laminate, for instance to improve the quality of laminated multilayer element of PV modules to increase the life time and performance of the final PV module.

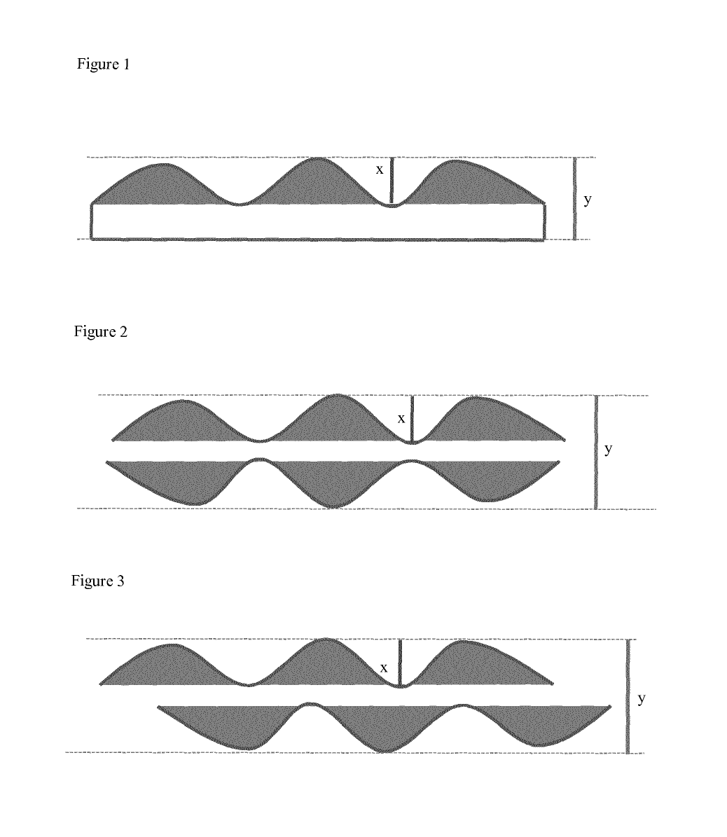

FIGS. 1 to 3 illustrate the measurement of the depth (%) of the recesses. In FIGS. 1 to 3, (x) denotes the depth (μm) of the deepest recess(s) and (y) the thickness (μm) of the thickest part of the layer (L) along the length of 1 mm cross-section of the layer element (L). FIGS. 1 to 3 show also examples of patterns of recesses on one or both surfaces of a layer (L).

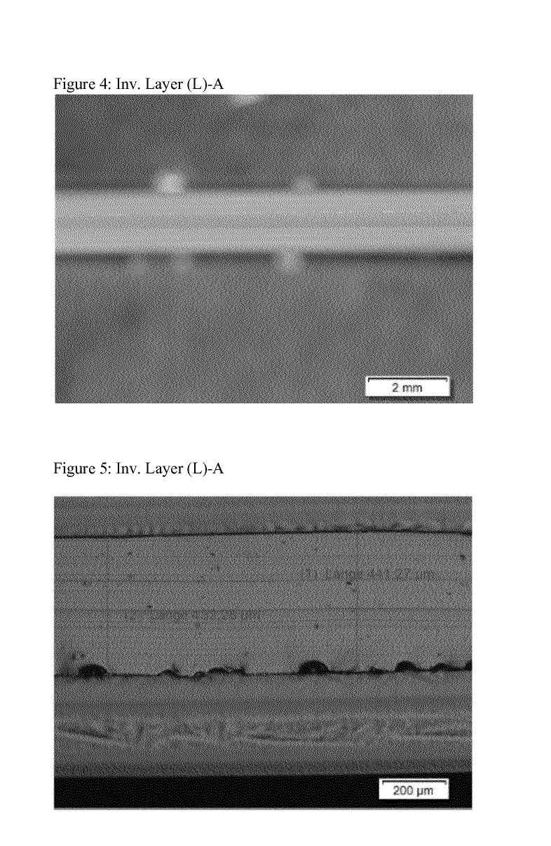

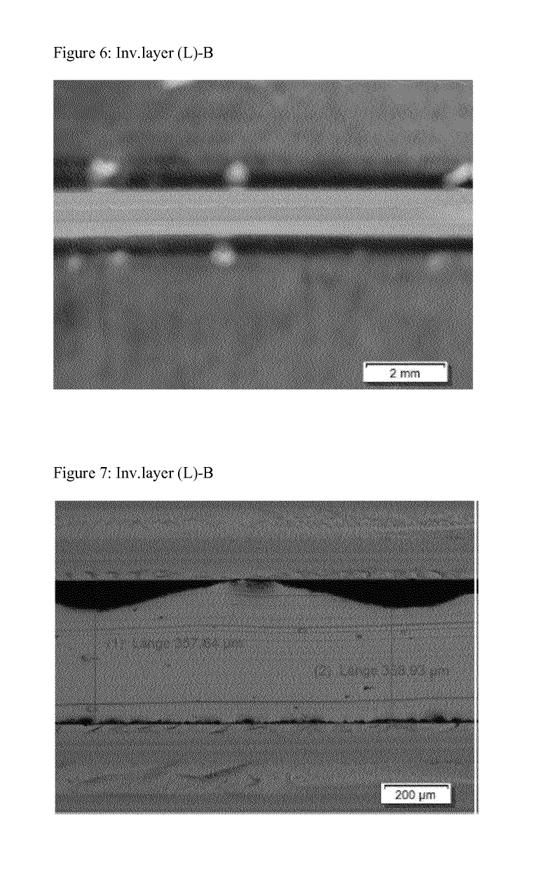

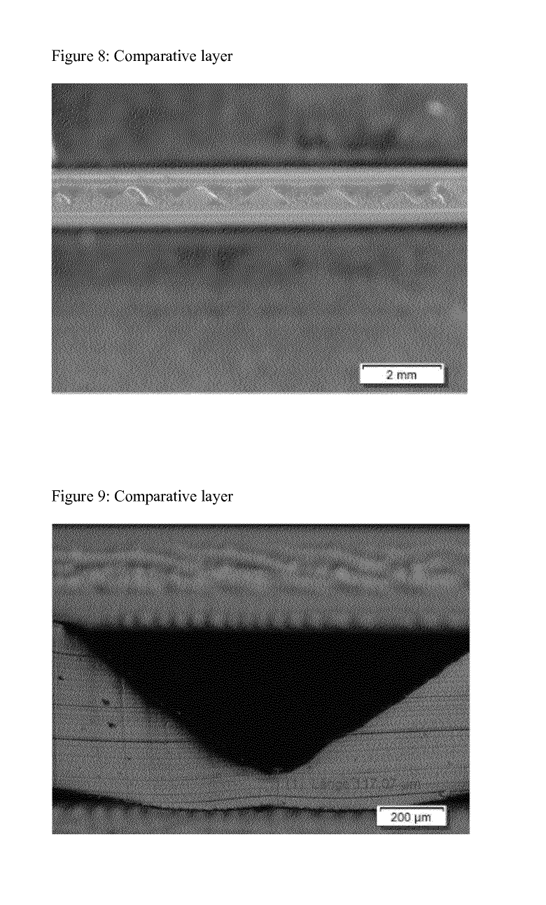

FIGS. 4 to 9 present microscopy photos (in two different magnification, scales 2 mm and 200 m) of the inventive and comparative layer element samples having varying depth (%) of recesses on one surface of each sample before lamination.

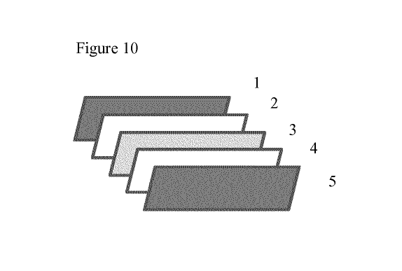

FIG. 10 illustrates one example of a photovoltaic module (PV) of the invention.

The term “Linge” in the figures means length.

Accordingly, the present invention provides a layer element (L) comprising an ethylene polymer composition (C) which comprises
a polymer of ethylene (a);
silane group(s) containing units (b); and wherein
the ethylene polymer composition (C) has an MFR₂ of less than 20 g/10 min when determined according to ISO 1133 (at 190° C.; and wherein
at least one of the layer surfaces of the layer element (L) is provided with a pattern of recesses.

“Layer element (L)” is referred herein also shortly as “layer (L)”.

“Ethylene polymer composition (C)” is referred herein also shortly as “polymer composition (C)” “composition”.

“At least one of the layer surfaces of the layer element (L)” is referred herein also shortly as “at least one layer surface”.

“Polymer of ethylene (P)” is referred herein also shortly as “polymer (a)”.

Surprisingly, the claimed layer element (L) with the specific layer surface of the invention provides highly consistent adhesion and easy handling of the layer element (L). Preferably, the at least one layer surface with recesses further provides a surface roughness property which is highly advantageous for lamination.

Moreover, the specific surface structure of layer (L) together with the specific polymer composition (C) comprising the polymer (a) combined with the silane group(s) containing units (b) enables to use lower MFR without the need of crosslinking using peroxide. Accordingly, the layer element (L) of the invention enables to use shorter lamination time, since e.g. evacuation time can be reduced.

Preferably, the depth (%) of the recesses of the at least one layer surface is below 70%, preferably below 60%, preferably below 50%, more preferably below 45%, of the thickness of the layer element (L), when measured in the cross-section of 1 mm long layer element (L) as described below under determination methods. The depth (%) of the recesses means herein the ratio of the deepest recess(s) to the thickness of the thickest part of the layer (L) along the length of 1 mm cross-section of the layer (L) element. FIGS. 1 to 3 illustrate the measurement of the depth (%) of the recesses. In FIGS. 1 to 3, (x) denotes the depth (μm) of the deepest recess(s) and (y) the thickness (μm) of the thickest part of the layer (L) along the length of a 1 mm cross-section of the layer element (L).

Preferably, the depth (%) of the recesses is at least 5% of the thickness of the layer (L) element, when measured in the cross-section of 1 mm long layer (L) sample as described below under Determination methods.

The layer element (L) can be a monolayer element or a multilayer element. In a monolayer element the “at least one layer surface” means at least one of the opposite layer surfaces of the layer (L). Moreover, both of the layer surfaces of a monolayer element can be provided with a pattern of recesses. In such case the pattern of recesses can be same or different, provided that at least one layer surface has the preferable recess depth (%) as defined above. In multilayer element “the at least one layer surface” means at least one of the opposite outermost layer surfaces of the multilayer layer element (L). Again, in case more than one surface of such multilayer element as layer (L) is provided with pattern of recesses, then such pattern of recesses can be same or different, provided that at least one layer surface has the preferable recess depth (%) as defined above. Moreover, part or all layers of said multilayer element as layer (L) can be produced at least partly by (co)extrusion, whereby, as evident for a skilled person, only those layer surfaces of such multilayer element which are to be integrated by lamination (and at least one of the outermost surfaces), contain the pattern of recesses.

The layer (L) is preferably a monolayer element.

As mentioned above, the layer (L) does not require crosslinking using peroxide, whereby the lamination time of layer (L) can be shorter. Accordingly, preferably the ethylene polymer composition (C) is without peroxide.

The layer (L) is highly suitable for lamination with other layer elements, preferably with layer elements of photovoltaic module.

Accordingly, the invention further provides a multilayer assembly comprising the layer element (L). Preferably the multilayer assembly is a photovoltaic multilayer assembly.

“Multilayer assembly” means herein the assembly of separate layer elements arranged to a multilayer structure before lamination, wherein at least one layer element is layer (L). The separate layer elements of the multilayer assembly can then be integrated (adhered) together preferably by lamination to form a multilayer laminate.

It is to be understood that part or all of the pattern of recesses of the at least one layer surface of layer (L) can remain, be deformed at least partly and/or the depth reduced or fully flattened in the formed multilayer laminate, as evident for a skilled person in the field. However, after the lamination, also the laminated layer (L) with optionally modified surface profile is referred herein as layer (L), since the initial pattern of recesses, as mentioned, can contribute in shortening the lamination process and provides i.a. advantageous adhesion properties and advantageous surface quality to the formed laminate (as well as to the final article) after the lamination, which extend the use life of the end article.

Accordingly, the invention further provides an article comprising a layer (L). Preferably, the article of the invention comprises a multilayer laminate comprising a layer element (L) of the invention, preferably a multilayer laminate of a photovoltaic (PV) module. The article of the invention is preferably a photovoltaic (PV) module.

The layer (L) and the assembly of layer elements of the invention are both highly suitable for producing various articles comprising two or more layer elements integrated together by lamination.

Furthermore, the invention provides a use of said layer element (L) for producing an article, preferably a photovoltaic module.

The invention further provides a process for producing layer (L), wherein at least one surface of a layer element (L) comprising the polymer composition (C) is embossed to form a pattern of recesses as defined above, below or in claims.

The invention further provides a process for producing an article by lamination comprising,

(i) an assembling step to arrange the layer element (L) of the invention with at least one further layer element to form of a multilayer assembly, wherein the at least one surface of layer (L) with the pattern of recesses of the invention is in contact with one of the outer surfaces of said further layer element of the assembly;
(ii) a heating step to heat up the formed multilayer assembly optionally, and preferably, in a chamber at evacuating conditions;
(iii) a pressing step to build and keep pressure on the multilayer assembly at the heated conditions for the lamination of the assembly to occur; and
(iv) a recovering step to cool and remove the obtained article comprising the multilayer laminate.

The process for producing an article by lamination is preferably a process for producing a photovoltaic (PV) module.

In the following preferred features of all variants and embodiments of the present invention are described unless explicitly stated to the contrary.

The polymer composition preferably comprises
a polymer of ethylene (a) selected from:
   (a1) a polymer of ethylene which optionally contains one or more comonomer(s) other than a polar comonomer of polymer (a2) and which bears functional groups containing units;
   (a2) a polymer of ethylene containing one or more polar comonomer(s) selected from (C₁-C₆)-alkyl acrylate or (C₁-C₆)-alkyl (C₁-C₆)-alkylacrylate comonomer(s), and optionally bears functional group(s) containing units other than said polar comonomer; or
   (a3) a polymer of ethylene containing one or more alpha-olefin comonomer selected from (C₁-C₁₀)-alpha-olefin comonomer, and optionally bears functional group(s) containing units; and
silane group(s) containing units (b).

The functional groups containing units of the polymer (a1) are other than said optional comonomer(s).

As well known “comonomer” refers to copolymerisable comonomer units.

It is preferred that the comonomer(s) of polymer (a), if present, is/are other than vinyl acetate comonomer. Preferably, the layer (L) is without (does not comprise) a copolymer of ethylene with vinyl acetate comonomer.

It is preferred that the comonomer(s) of polymer (a), if present, is/are other than alpha,beta ethylenically unsaturated carboxylic acid comonomer and/or ionomers derived therefrom. Preferably, the layer (L) is without (does not comprise) a copolymer of ethylene with alpha,beta ethylenically unsaturated carboxylic acid comonomer and/or ionomers derived therefrom.

Preferably, the thermoplastic layer element (L) is free of copolymer of ethylene with vinyl acetate comonomer and of copolymer of ethylene with ethylene with alpha,beta ethylenically unsaturated carboxylic acid comonomer and/or ionomers derived.

It is preferred that the composition (C) of the layer (L) comprises, preferably consists of,
a polymer of ethylene (a) as defined above below or in claims;
silane group(s) containing units (b) as defined above below or in claims; and
additive(s) and optionally filler(s), preferably additive(s), as defined below. More preferably, the layer (L) consists of the polymer composition (C).

The content of optional comonomer(s), if present in polymer (a1), polar commoner(s) of polymer (a2) or alpha-olefin comonomer(s) of polymer (a3), is preferably of 4.5 to 18 mol %, preferably of 5.0 to 18.0 mol %, preferably of 6.0 to 18.0 mol %, preferably of 6.0 to 16.5 mol %, more preferably of 6.8 to 15.0 mol %, more preferably of 7.0 to 13.5 mol %, when measured according to “Comonomer contents” as described below under the “Determination methods”.

The silane group(s) containing units (b) and the polymer (a) can be present as separate components in the polymer composition (C) of the layer (L), i.e. silane group(s) containing units (b) are not chemically bonded to the polymer (a), but said components are physically mixed to form a blend (composition), or the silane group(s) containing units (b) can be present as a comonomer of the polymer (a) or as a compound grafted chemically to the polymer (a).

Accordingly, in copolymerization the silane group(s) containing units (b) are copolymerized as comonomer with ethylene monomer during the polymerization process of polymer (a). In grafting, the silane group(s) containing units (b) component (compound) is, at least partly, reacted chemically, typically using e.g. a radical forming agent, such as peroxide, with the polymer (a) after the polymerization of the polymer (a). Such chemical reaction may take place before or during the lamination process of the invention. In general, copolymerisation and grafting of the silane group(s) containing units to ethylene are well known techniques and well documented in the polymer field and within the skills of a skilled person. It is also well known that the use of peroxide in grafting decreases the melt flow rate (MFR) of an ethylene polymer due to a simultaneous crosslinking reaction. Accordingly grafting can bring limitation to the choice of the MFR of polymer (a) as a starting polymer.

Preferably the silane group(s) containing units (b) are present in the polymer (a). More preferably, the polymer (a) bears functional group(s) containing units, whereby said functional group(s) containing units are said silane group(s) containing units (b).

Most preferably, the polymer (a) comprises functional group(s) containing units which are the silane group(s) containing units (b) as comonomer in the polymer (a). The copolymerisation provides more uniform incorporation of the units (b). Moreover, the copolymerisation does not require the use of peroxide, which, as said, is typically needed for the grafting of said units to polyethylene, whereby any drawbacks, like limitation to MFR of the starting polymer (a) and/or any by-products formed from peroxide (which can deteriorate the quality of the polymer) can be avoided.

The polymer composition (C) more preferably comprises
polymer (a) which is selected from
(a1) a polymer of ethylene which optionally contains one or more comonomer(s) other than the polar comonomer of polymer (a2) and which bears functional groups containing units other than said optional comonomer(s); or
(a2) a polymer of ethylene containing one or more polar comonomer(s) selected from (C₁-C₆)-alkyl acrylate or (C₁-C₆)-alkyl (C₁-C₆)-alkylacrylate comonomer(s), and optionally bears functional group(s) containing units other than said polar comonomer; and
silane group(s) containing units (b).

Furthermore, the comonomer(s) of polymer (a) is/are preferably other than the alpha-olefin comonomer as defined above.

In one preferable embodiment A1, the polymer composition comprises a polymer (a) which is the polymer of ethylene (a1) which bears the silane group(s) containing units (b) as the functional groups containing units (also referred herein as “polymer (a1) which bears the silane group(s) containing units (b)” or “polymer (a1)”). In this embodiment A1, the polymer (a1) preferably does not contain, i.e. is without, a polar comonomer of polymer (a2) or an alpha-olefin comonomer.

In one equally preferable embodiment A2,

the polymer composition comprises
a polymer (a) which is the polymer of ethylene (a2) containing one or more polar comonomer(s) selected from (C₁-C₆)-alkyl acrylate or (C₁-C₆)-alkyl (C₁-C₆)-alkylacrylate, preferably one (C₁-C₆)-alkyl acrylate, and bears functional group(s) containing units other than said polar comonomer; and
silane group(s) containing units (b); more preferably
   the polymer composition comprises a polymer (a) which is the polymer of ethylene (a2) containing one or more polar comonomer(s) selected from (C₁-C₆)-alkyl acrylate or (C₁-C₆)-alkyl (C₁-C₆)-alkylacrylate comonomer(s), and bears the silane group(s) containing units (b) as the functional group(s) containing units (also referred as “polymer (a2) with the polar comonomer and the silane group(s) containing units (b)” or “polymer (a2)”).

The “polymer (a1) or polymer (a2)” is also referred herein as “polymer (a1) or (a2)”.

In more preferable embodiment, the silane group(s) containing units (b) as the functional group(s) containing units are present as a comonomer in the polymer (a1) or polymer (a2). This preferable embodiment further contributes to feasible flowability/processability properties thereof. Moreover, in this embodiment the polymer (a1) or polymer (a2) does not form any significant volatiles during e.g. lamination process of the layer (L). Any decomposition products thereof could be formed only at a temperature close to 400° C. Therefore, the holding time during lamination can be shortened significantly. Also the quality of the obtained laminate is highly desirable, since premature crosslinking, presence and removal of by-products, which are formed during the crosslinking reaction with e.g. peroxide, and may cause bubble formation, can be avoided.

The content of the polar comonomer present in the polymer (a2) is preferably of 0.5 to 30.0 mol %, 2.5 to 20.0 mol %, preferably 4.5 to 18 mol %, preferably of 5.0 to 18.0 mol %, preferably of 6.0 to 18.0 mol %, preferably of 6.0 to 16.5 mol %, more preferably of 6.8 to 15.0 mol %, more preferably of 7.0 to 13.5 mol %, when measured according to “Comonomer contents” as described below under the “Determination methods”. The polymer (a2) with the polar comonomer and the silane group(s) containing units (b) contains preferably one polar comonomer as defined above, below or in claims. In a preferable embodiment of A1, said polar comonomer(s) of polymer of ethylene (a2) is a polar comonomer selected from (C₁-C₄)-alkyl acrylate or (C₁-C₄)-alkyl methacrylate comonomer(s) or mixtures thereof. More preferably, said polymer (a2) contains one polar comonomer which is preferably (C₁-C₄)-alkyl acrylate comonomer.

The most preferred polar comonomer of polymer (a2) is methyl acrylate. The methyl acrylate has very beneficial properties such as excellent wettability, adhesion and optical (e.g. transmittance) properties, which contribute to the lamination process and to the quality of the obtained laminate. Moreover, the thermostability properties of methyl acrylate (MA) comonomer are also highly advantageous. For instance, methyl acrylate is the only acrylate which cannot go through the ester pyrolysis reaction, since does not have this reaction path. As a result, if the polymer (a2) with MA comonomer degrades at high temperatures, then there is no harmful acid (acrylic acid) formation which improves the quality and life cycle of the laminate (L) and the final article thereof. This is not the case e.g. with vinyl acetate of EVA which, on the contrary, can go through the ester pyrolysis reaction, and if degrade, would form the harmful acid and for the acrylates also volatile olefinic by-products.

The polymer composition comprising the polymer (a) and the silane group(s) containing units (b), more preferably the polymer (a1) or (a2), thus enables, if desired, to decrease the MFR of the polymer (a), preferably polymer (a1) or (a2), compared to prior art and thus offers higher resistance to flow during the lamination step. As a result, the preferable MFR can further contribute, if desired, to the quality of the final multilayer laminate, such as the preferable final PV module, and to the short lamination cycle time obtainable by the process of the invention.

The melt flow rate, MFR₂, of the polymer composition, preferably of the polymer (a), preferably of the polymer (a1) or (a2), is preferably less than 20 g/10 min, preferably less than 15 g/10 min, preferably from 0.1 to 13 g/10 min, preferably from 0.2 to 10 g/10 min, preferably from 0.3 to 8 g/10 min, more preferably from 0.4 to 6, g/10 min (according to ISO 1133 at 190° C. and at a load of 2.16 kg).

The polymer composition comprising the polymer (a) and the silane group(s) containing units (b), more preferably the polymer (a1) or (a2), present in the layer (L) has preferably a Shear thinning index, SHI_{0.05/300}, of 30.0 to 100.0, preferably of 40.0 to 80.0, when measured according to “Rheological properties: Dynamic Shear Measurements (frequency sweep measurements)” as described below under “Determination Methods”.

Accordingly, the combination of the preferable SHI and the preferable MFR range of the polymer composition, preferably of the polymer (a), more preferably the polymer (a1) or (a2), further contributes to the quality of the final multilayer laminate, such as of the multilayer laminate of the preferable final PV module.

The preferable SHI range further contributes to the lamination process of layer (L), since such preferable rheology property causes less stress on the PV cell element.

The composition, more preferably the polymer (a), more preferably of the polymer (a1) or (a2), preferably has a melting temperature of 120° C. or less, preferably 110° C. or less, more preferably 100° C. or less and most preferably 95° C. or less, when measured according to ASTM D3418 as described under “Determination Methods”. Preferably the melting temperature of the composition, more preferably the polymer (a), more preferably of the polymer (a1) or (a2), is 70° C. or more, more preferably 75° C. or more, even more preferably 78° C. or more, when measured as described below under “Determination Methods”. The preferable melting temperature is beneficial for lamination process, since the time of the melting/softening step can be reduced.

Typically, and preferably the density of the composition, preferably of the polymer of ethylene (a), more preferably of the polymer (a1) or (a2), is higher than 860 kg/m³. Preferably the density is not higher than 970 kg/m³, and preferably is from 920 to 960 kg/m³, according to ISO 1872-2 as described below under “Determination Methods”.

The silane group(s) containing units (b) as a comonomer or as a compound is suitably a hydrolysable unsaturated silane compound represented by the formula

R1SiR2_{q}Y_{3-q} (I)

wherein
R1 is an ethylenically unsaturated hydrocarbyl, hydrocarbyloxy or (meth)acryloxy hydrocarbyl group,
each R2 is independently an aliphatic saturated hydrocarbyl group,
Y which may be the same or different, is a hydrolysable organic group and
q is 0, 1 or 2.

Special examples of the unsaturated silane compound are those wherein R1 is vinyl, allyl, isopropenyl, butenyl, cyclohexanyl or gamma-(meth)acryloxy propyl; Y is methoxy, ethoxy, formyloxy, acetoxy, propionyloxy or an alkyl- or arylamino group; and R2, if present, is a methyl, ethyl, propyl, decyl or phenyl group.

Further suitable silane compounds or, preferably, comonomers are e.g. gamma-(meth)acryloxypropyl trimethoxysilane, gamma(meth)acryloxypropyl triethoxysilane, and vinyl triacetoxysilane, or combinations of two or more thereof.

As a suitable subgroup of compound or comonomer, preferably comonomer, of formula (I) is an unsaturated silane compound or, preferably, comonomer of formula (II)

CH₂=CHSi(OA)₃ (II)

wherein each A is independently a hydrocarbyl group having 1-8 carbon atoms, suitably 1-4 carbon atoms.

In one embodiment of silane group(s) containing units (b) of the invention, comonomer or compound of formula (I), preferably of formula (II), are vinyl trimethoxysilane, vinyl bismethoxyethoxysilane, vinyl triethoxysilane, vinyl trimethoxysilane.

The amount of the silane group(s) containing units (b) present in the composition, preferably in the polymer (a), is from 0.01 to 1.00 mol %, suitably from 0.05 to 0.80 mol %, suitably from 0.10 to 0.60 mol %, suitably from 0.10 to 0.50 mol %, when determined according to “Comonomer contents” as described below under “Determination Methods”.

As already mentioned the silane group(s) containing units (b) are present in the polymer (a), more preferably in the polymer (a1) or (a2), as a comonomer.

In a more preferable embodiment A1, the polymer (a1) bears functional groups containing which are silane group(s) containing units (b) as comonomer according to formula (I), more according to formula (II), more preferably according to formula (II) selected from vinyl trimethoxysilane, vinyl bismethoxyethoxysilane, vinyl triethoxysilane or vinyl trimethoxysilane comonomer, as defined above or in claims. Most preferably in this embodiment A1 the polymer (a1) is a copolymer of ethylene with vinyl trimethoxysilane, vinyl bismethoxyethoxysilane, vinyl triethoxysilane or vinyl trimethoxysilane comonomer, preferably with vinyl trimethoxysilane comonomer.

In an equally preferable embodiment A2, the polymer (a2) is a copolymer of ethylene with a (C₁-C₄)-alkyl acrylate comonomer and bears functional groups containing units which are silane group(s) containing units (b) as comonomer according to formula (I), more preferably according to formula (II), more preferably according to formula (II), more preferably selected from vinyl trimethoxysilane, vinyl bismethoxyethoxysilane, vinyl triethoxysilane or vinyl trimethoxysilane comonomer, as defined above or in claims. Most preferably in this embodiment A2 the polymer (a) is a polymer (a2) which is a copolymer of ethylene with methyl acrylate comonomer and with vinyl trimethoxysilane, vinyl bismethoxyethoxysilane, vinyl triethoxysilane or vinyl trimethoxysilane comonomer, preferably with vinyl trimethoxysilane comonomer.

More preferably the polymer (a) is a copolymer of ethylene (a1) with vinyl trimethoxysilane comonomer or a copolymer of ethylene (a2) with methylacrylate comonomer and with vinyl trimethoxysilane comonomer. The preferred polymer (a) is a copolymer of ethylene (a2) with methylacrylate comonomer and with vinyl trimethoxysilane comonomer.

As said, the at least one layer (L) is preferably not crosslinked using peroxide.

If desired, depending on the end application, the composition can be crosslinked via silane group(s) containing units (b) using a silanol condensation catalyst (SCC), which is selected from the group of carboxylates of tin, zinc, iron, lead or cobalt or aromatic organic sulphonic acids, before or during the lamination process of the invention. Such SCC are for instance commercially available.

It is to be understood that the SCC as defined above are those conventionally supplied for the purpose of crosslinking.

The silanol condensation catalyst (SCC), which is can optionally be present in the composition of layer (L), is more preferably selected from the group C of carboxylates of metals, such as tin, zinc, iron, lead and cobalt; from a titanium compound bearing a group hydrolysable to a Brönsted acid (preferably as described in WO 2011/160964 of Borealis, included herein as reference), from organic bases; from inorganic acids; and from organic acids; suitably from carboxylates of metals, such as tin, zinc, iron, lead and cobalt, from titanium compound bearing a group hydrolysable to a Brönsted acid as defined above or from organic acids, suitably from dibutyl tin dilaurate (DBTL), dioctyl tin dilaurate (DOTL), particularly DOTL; titanium compound bearing a group hydrolysable to a Brönsted acid as defined above; or an aromatic organic sulphonic acid, which is suitably an organic sulphonic acid which comprises the structural element:

Ar(SO₃H)ₓ (II)

wherein Ar is an aryl group which may be substituted or non-substituted, and if substituted, then suitably with at least one hydrocarbyl group up to 50 carbon atoms, and x is at least 1; or a precursor of the sulphonic acid of formula (II) including an acid anhydride thereof or a sulphonic acid of formula (II) that has been provided with a hydrolysable protective group(s), e.g. an acetyl group that is removable by hydrolysis. Such organic sulphonic acids are described e.g. in EP736065, or alternatively, in EP1309631 and EP1309632.

In a preferable embodiment no silane condensation catalyst (SCC), which is selected from the SCC group of tin-organic catalysts or aromatic organic sulphonic acids the SCC, is present in polymer composition of layer (L). In a further preferable embodiment no peroxide or silane condensation catalyst (SCC), which is selected from the SCC group of tin-organic catalysts or aromatic organic sulphonic acids the SCC, is present in polymer composition of layer (L). As already mentioned, with the present preferable polymer composition the crosslinking of the layer (L) can be avoided which contributes to achieve the good quality of the multilayer laminate and, additionally, to shorten the lamination cycle time without deteriorating the quality of the formed multilayer laminate. For instance, the recovering step (iv) of the process can be short, since time consuming removal of by-products, which are typically formed in the prior art peroxide crosslinking, is not needed.

Preferably, the amount of the optional crosslinking agent (g) is of 0 to 0.1 mol/kg polymer of ethylene (a). Preferably the crosslinking agent (g) is present and in an amount of 0.00001 to 0.1, preferably of 0.0001 to 0.01, more preferably 0.0002 to 0.005, more preferably of 0.0005 to 0.005, mol/kg polymer of ethylene (a).

The polymer (a) of the composition can be e.g. commercially available or can be prepared according to or analogously to known polymerization processes described in the chemical literature.

In a preferable embodiment the polymer (a), preferably the polymer (a1) or (a2), is produced by polymerising ethylene suitably with silane group(s) containing comonomer (=silane group(s) containing units (b)) as defined above and with optional other comonomer(s), like in case of polymer (a2) with polar comonomer, in a high pressure (HP) process using free radical polymerization in the presence of one or more initiator(s) and optionally using a chain transfer agent (CTA) to control the MFR of the polymer. The HP reactor can be e.g. a well-known tubular or autoclave reactor or a mixture thereof, suitably a tubular reactor. The high pressure (HP) polymerisation and the adjustment of process conditions for further tailoring the other properties of the polymer depending on the desired end application are well known and described in the literature, and can readily be used by a skilled person. Suitable polymerisation temperatures range up to 400° C., suitably from 80 to 350° C. and pressure from 70 MPa, suitably 100 to 400 MPa, suitably from 100 to 350 MPa. The high pressure polymerization is generally performed at pressures of 100 to 400 MPa and at temperatures of 80 to 350° C. Such processes are well known and well documented in the literature and will be further described later below.

The incorporation of the comonomer(s), if present, and optionally, and preferably, the silane group(s) containing units (b) suitably as comonomer as well as comonomer(s) and the control of the comonomer feed to obtain the desired final content of said comonomers and of optional, and preferable, silane group(s) containing units (b) as the comonomer can be carried out in a well-known manner and is within the skills of a skilled person.

Further details of the production of ethylene (co)polymers by high pressure radical polymerization can be found i.a. in the Encyclopedia of Polymer Science and Engineering, Vol. 6 (1986), pp 383-410 and Encyclopedia of Materials: Science and Technology, 2001 Elsevier Science Ltd.: “Polyethylene: High-pressure, R. Klimesch, D. Littmann and F.-O. Mäling pp. 7181-7184.

Such HP polymerisation results in a so called low density polymer of ethylene (LDPE), herein to polymer (a). The term LDPE has a well-known meaning in the polymer field and describes the nature of polyethylene produced in HP, i.e. the typical features, such as different branching architecture, to distinguish the LDPE from PE produced in the presence of an olefin polymerisation catalyst (also known as a coordination catalyst). Although the term LDPE is an abbreviation for low density polyethylene, the term is understood not to limit the density range, but covers the LDPE-like HP polyethylenes with low, medium and higher densities.

In one variant the composition of the invention suitably comprises additives other than fillers (like flame retardants (FRs), preferably the composition of the invention suitably comprises additives other than filler, pigment, carbon black or flame retardant. Then the composition, comprises, preferably consists of, based on the total amount (100 wt %) of the composition,
90 to 99.9999 wt % of the polymer (a) and the silane group(s) containing units (b); whereby usually the content of silane group(s) containing units (b) is 0.01 to 1.00 mol % based on the composition); and
0.0001 to 10 wt % of the additives, preferably 0.0001 and 5.0 wt %, like 0.0001 and 2.5 wt %.

Above and below, the amount of polymer (a) and silane group(s) containing units (b) is a combined amount (wt %), since silane group(s) containing units (b) can be part of the polymer (a), e.g. incorporated to polymer (a) by grafting or copolymerization, preferably by copolymerization.

The optional additives are e.g. conventional additives suitable for the desired end application and within the skills of a skilled person, including without limiting to, preferably at least antioxidant(s) and UV light stabilizer(s), and may also include metal deactivator(s), clarifier(s), brightener(s), acid scavenger(s), as well as slip agent(s) etc. Each additive can be used e.g. in conventional amounts, the total amount of additives present in the composition (C) being preferably as defined above. Such additives are generally commercially available and are described, for example, in “Plastic Additives Handbook”, 5th edition, 2001 of Hans Zweifel.

In another variant the composition of the invention comprises in addition to the suitable additives as defined above also one or more of filler, pigment, carbon black or flame retardant. Then the composition comprises, preferably consists of, based on the total amount (100 wt %) of the composition,
30 to 90 wt %, suitably 40 to 70 wt %, of the polymer (a) and the silane group(s) containing units (b) whereby usually the content of silane group(s) containing units (b) is 0.01 to 1.00 mol % based on the composition;
up to 70 wt %, suitably 30 to 60 wt %, of the one or more of filler, pigment, carbon black or flame retardant and the suitable additives.

Optional fillers, pigments, carbon black or flame retardants, are typically conventional and commercially available. Suitable optional flame retardants are e.g. magensiumhydroxide, ammonium polyphosphate etc. filler, pigment, carbon black or flame retardant.

In the preferred embodiment the composition comprises, preferably consists of,
90 to 99.9999 wt %, of the polymer (a) and the silane group(s) containing units (b) whereby usually the content of silane group(s) containing units (b) is 0.01 to 1.00 mol % based on the composition;
0.0001 to 10 wt % additives and optionally one or more of filler, pigment, carbon black or flame retardant fillers, preferably 0.0001 to 10 wt % additives and no fillers.

In a preferable embodiment the polymer composition consists of the polymer (a) as the only polymeric component(s). “Polymeric component(s)” exclude herein any carrier polymer(s) of optional additive or filler, pigment, carbon black or flame retardant, e.g. carrier polymer(s) used in master batch(es) of additive(s) or, respectively, filler, pigment, carbon black or flame retardant, optionally present in the composition of the layer (L). Such optional carrier polymer(s) are calculated to the amount of the respective additive or, respectively, filler based on the amount (100%) of the polymer composition.

Preferably the layer (L) consists of the polymer composition.

The layer (L) according to the present invention is particularly suitable as a layer element of a multilayer element of an article, preferably of a photovoltaic (PV) module.

In the preferable layer (L), the depth (%) of the recesses of the at least one layer surface is 70 to 5%, preferably below 60 to 5%, preferably below 50 to 5%, more preferably below 45 to 5%, more preferably below 30 to 5%, of the thickness of the layer element (L), when measured in the cross-section of 1 mm long layer element (L) as described below under Determination methods.

The shape of the recesses is not limited and can be chosen by a skilled person depending on the end application of the layer (L). The shape of the recesses can be for instance of any conventional shape. Moreover, the pattern of recesses can have e.g. any conventional design and can be discontinuous or continuous. For instance, the recesses can form “channels” or “pyramide” type discontinuous recesses on the outer surface of the layer (L), as well known in the art. Again the design of the pattern can be chosen by a skilled person depending on the end application of layer (L).

As mentioned, the layer (L) can have a pattern of recesses on both outer surfaces. The patterns can be same or different and at least one of said surfaces is provided with the pattern of recesses of the invention. Examples of patterns of recesses on one or both surfaces of a layer (L) are illustrated in FIGS. 1 to 3.

The pattern of the recesses of the at least one layer surface of the layer (L) of the invention is preferably embossed, i.e. provided by embossing. In general, embossing means to change an outer surface of an article, e.g. layer element, from flat to shaped (also called textured), i.e. to form recesses, so that some areas are raised relative to other areas. The embossing has a well-known meaning in the art and can e.g. be used to modify the surface properties, e.g. physical properties, of a film. There are different embossing techniques in the state of the art.

The invention thus further provides a process for producing layer (L), wherein at least one surface of a layer element (L) comprising the polymer composition (C) is embossed to form a pattern of recesses as defined above, below or in claims.

Preferably, the at least one outer surface of the layer element (L) is provided by rotary embossing which has a well-known meaning. In rotary embossing the material, e.g. film to be embossed, is conventionally passed between embossing rollers using heat and pressure. The rotary embossing equipment is typically arranged with an embossing nip, which is the area where two embossing rollers come into contact. At least one of the rollers is encarved to a certain pattern of recesses to provide the recesses on at least one of the outer surfaces of the layer (L). The material of the rollers can vary. Moreover, the surfaces of the two rollers can be of the same or different material, as known in the art. As an example of embossing rollers, so called R/S (rubber-to-steel) rollers, wherein one roller has rubber surface and the other roller has steel surface, or S/S (steel to steel) rollers, wherein the surface of the both surface is steel, can be mentioned. Embossing equipments are commercially available and the choice of type and embossing pattern are within the skills of a skilled person. The embossing equipment can e.g. be a calender equipment, whereby at least one of the two calendars is embossed to transfer the pattern of recesses onto the surface of a layer element (L).

More preferably the rotary embossing is preferably arranged to the production line of the layer (L), whereby after the formation of a layer element e.g. by (co)extrusion, the formed layer element is then subjected to an embossing step to form the layer (L). Preferably, said rotary embossing step is part of a production process of the layer element, preferably follows extrusion the process, like cast film (co)extrusion process, of a layer element. Such layer element production equipment, like film extrusion equipment, including the embossing equipment are conventional and well-known in the field. For instance, any suitable commercially available film extrusion equipment and embossing equipment can be used to produce the layer (L).

As mentioned, the layer (L) can be a monolayer or multilayer element, preferably a monolayer element.

As already mentioned, with the present composition preferably the crosslinking of the layer (L) can be avoided which contributes to achieve the good quality of the multilayer laminate and, additionally, to shorten the lamination cycle time without deteriorating the quality of the formed multilayer laminate. For instance, the recovering step (iv) of the process can be short, since time consuming removal of by-products, which are typically formed in the prior art peroxide crosslinking, is not needed.

The layer (L) can then be used to form articles comprising multilayer elements.

Preferably, said further layer element is a rigid layer element.

The invention further provides a multilayer assembly comprising the layer element (L). Preferably the multilayer assembly is a photovoltaic multilayer assembly.

The invention further provides an article comprising a layer (L). The article preferably comprises a multilayer laminate comprising a layer element (L) of the invention, preferably a multilayer laminate of a photovoltaic (PV) module.

The preferred article of the invention is a photovoltaic (PV) module comprising, in the given order, a protective front layer element, preferably a glass layer element, a front encapsulation layer element, a photovoltaic element, a rear encapsulation layer element and a protective back layer element, wherein the front encapsulation layer element and/or the rear encapsulation layer element, preferably at least the front encapsulation layer element, is the layer (L) comprising a polymer composition (C) of the invention which comprises
a polymer of ethylene (a) as defined above or in claims;
silane group(s) containing units (b);
   and wherein the polymer composition (C) has a melt flow rate, MFR₂, of less than 20 g/10 min (according to ISO 1133 at 190° C. and at a load of 2.16 kg).

In case only one side of the PV module is towards the sun light, then the “front encapsulation layer element” means the encapsulation layer element which is on the sun light facing side of the cell. In case of bifacial PV module (i.e. both sides of the PV module can receive sun light), then the terms “front encapsulation layer element” and “rear encapsulation layer element” are naturally interchangeable.

The pattern of recesses of the at least one surface of layer (L) as said front and/or rear encapsulation layer element can independently be in contact with a surface of the protective front layer element, and/or, respectively, in contact with a surface of the protective back layer element, or said pattern of recesses of the at least one surface of layer (L) as said front and/or rear encapsulation layer element can be in contact with a surface of the photovoltaic element. Similarly, in case the pattern of recesses of the invention are on both surfaces (sides) of the layer (L) as said front and/or rear encapsulation layer element, then both the surface of the protective front layer element and/or, respectively, of the protective back layer element and the surface(s) of the photovoltaic element is/are in contact with said pattern of recesses of the layer(s) (L) as said front and/or rear encapsulation layer element.

More preferably, the layer (L) as the front and/or rear layer encapsulation element is a monolayer element.

The preferred article of the invention is a photovoltaic (PV) module comprising, in the given order, a protective front layer element, preferably a glass layer element, a front encapsulation layer element, a photovoltaic element, a rear encapsulation layer element and a protective back layer element, preferably a glass layer element, wherein the front encapsulation layer element and the rear encapsulation layer element are the layer (L) comprising a polymer composition (C) of the invention which comprises
a polymer of ethylene (a) as defined above or in claims;
silane group(s) containing units (b);
   and wherein the polymer composition (C) has a melt flow rate, MFR₂, of less than 20 g/10 min (according to ISO 1133 at 190° C. and at a load of 2.16 kg).

In this embodiment one or both, preferably both, of the protective front layer element and the protective back layer element (backsheet element) are glass layer elements.

Accordingly, the final photovoltaic module can be rigid or flexible, preferably rigid. The rigid PV module of the invention preferably contains a rigid protective front layer element, such as a glass layer element, and a flexible or rigid, preferably rigid, protective back layer element (backsheet layer element) can e.g. a glass layer element. In flexible modules all the above elements are flexible, whereby the protective front layer element can be e.g. a fluorinated layer made from polyvinylfluoride (PVF) or polyvinylidenefluoride (PVDF) polymer, and the backsheet layer element is typically a polymeric layer element.

Moreover, the final PV module of the invention can for instance be arranged to a metal, such as aluminum, frame.

All said terms have a well-known meaning in the art.

The material of the above elements is well known in the prior art and can be chosen by a skilled person depending on the desired PV module.

The above exemplified layer elements can be monolayer or multilayer elements.

The “photovoltaic element” means that the element has photovoltaic activity. The photovoltaic element can be e.g. an element of photovoltaic cell(s), which has a well-known meaning in the art. Silicon based material, e.g. crystalline silicon, is a non-limiting example of materials used in photovoltaic cell(s). Crystalline silicon material can vary with respect to crystallinity and crystal size, as well known to a skilled person. Alternatively, the photovoltaic element can be a substrate layer on one surface of which a further layer or deposit with photovoltaic activity is subjected, for example a glass layer, wherein on one side thereof an ink material with photovoltaic activity is printed, or a substrate layer on one side thereof a material with photovoltaic activity is deposited. For instance, in well-known thin film solutions of photovoltaic elements e.g. an ink with photovoltaic activity is printed on one side of a substrate, which is typically a glass substrate.

The photovoltaic element is most preferably an element of photovoltaic cell(s). “Photovoltaic cell(s)” means herein a layer element(s) of photovoltaic cells, as explained above, together with connectors.

The PV module may comprise other layer elements as well, as known in the field of PV modules. Moreover, any of the other layer elements can be mono or multilayer elements.

In some embodiments there can be an adhesive layer between the different layer elements and/or between the layers of a multilayer element, as well known in the art. Such adhesive layers have the function to improve the adhesion between the two elements and have a well-known meaning in the lamination field. The adhesive layers are differentiated from the other functional layer elements of the PV module, e.g. those as specified above, below or in claims, as evident for a skilled person in the art. Preferably, there is no adhesive layer between the protective front layer element and the front encapsulation layer element and/or, preferably and, no adhesive layer between the protective back layer element and the rear encapsulation layer element. Further preferably, there is no adhesive layer between the photovoltaic element and the front encapsulation layer element and/or, preferably and, no adhesive layer between the photovoltaic layer element and the rear encapsulation layer element.

As well-known in the PV field, the thickness of the above mentioned elements, as well as any additional elements, of the laminated photovoltaic module of the invention can vary depending on the desired photovoltaic module embodiment and can be chosen accordingly by a person skilled in the PV field.

As a non-limiting example only, the thickness of the front and/or back, preferably of the front and back, encapsulation monolayer or multilayer element, preferably of front and/or back, preferably of the front and back, encapsulation monolayer is typically up to 2 mm, preferably up to 1 mm, typically 0.3 to 0.6 mm.

As a non-limiting example only, the thickness of the rigid protective front layer element, e.g. glass layer, is typically up to 10 mm, preferably up to 8 mm, preferably 2 to 4 mm.

As a non-limiting example only, the thickness of the flexible protective back (backsheet) layer element, e.g. polymeric (multi)layer element, is typically up to 700, like 90 to 700, suitably 100 to 500, such as 100 to 400, μm. As a non-limiting example only, the thickness of the rigid protective back (backsheet) layer element, e.g. glass layer, is typically up to 10 mm, preferably up to 8 mm, preferably 2 to 4 mm.

As a non-limiting example only, the thickness of a photovoltaic element, e.g. an element of monocrystalline photovoltaic cell(s), is typically between 100 to 500 microns.

The separate elements of PV module, e.g. protective front layer element, a front encapsulation layer element, a photovoltaic element, a rear encapsulation layer element and the protective back layer element, i.e. backsheet layer element, can be produced in a manner well known in the photovoltaic field or are commercially available. The PV layer element, preferably the front encapsulation layer element and/or rear encapsulation layer element as layer (L) can be produced as described above in context of layer (L).

FIG. 10 is a schematic picture of a typical PV module of the invention comprising a protective front layer element (1), a front encapsulation layer element (2), a photovoltaic element (3), a rear encapsulation layer element (4) and the protective back layer element (5).

It is also to be understood that part of the layer elements can be in integrated form, i.e. two or more of said PV elements can be integrated together, e.g. by lamination, before subjecting to the lamination process of the invention.

The invention further provides a process for producing an article of the invention, as defined above, below or in claims, by lamination comprising,

(i) an assembling step to arrange the layer element (L) of the invention with at least one further layer element to form of a multilayer assembly, wherein the at least one surface of layer (L) with the pattern of recesses of the invention is in contact with one of the outer surfaces of said further layer element of the assembly;
(ii) a heating step to heat up the formed multilayer assembly optionally, and preferably, in a chamber at evacuating conditions;
(iii) a pressing step to build and keep pressure on the multilayer assembly at the heated conditions for the lamination of the assembly to occur; and
(iv) a recovering step to cool and remove the obtained article comprising the multilayer laminate.

The process for producing an article by lamination is preferably a process for producing a photovoltaic (PV) module of the invention, as defined above, below or in claims, comprising, in the given order, a protective front layer element, a front encapsulation layer element, a photovoltaic element, a rear encapsulation layer element and a protective back layer element, wherein the front encapsulation layer element and/or the rear encapsulation layer element, preferably at least the front encapsulation layer element, is the layer (L) comprising a polymer composition (C) of the invention which comprises
a polymer of ethylene (a) as defined above or in claims;
silane group(s) containing units (b);
   and wherein the polymer composition (C) has a melt flow rate, MFR₂, of less than 20 g/10 min (according to ISO 1133 at 190° C. and at a load of 2.16 kg); and wherein the process comprises the steps of:
   (i) an assembling step to arrange the protective front layer element, the front encapsulation layer element, the photovoltaic element, the rear encapsulation layer element and the protective back layer element, in given order, to form of a photovoltaic module assembly;
   (ii) a heating step to heat up the photovoltaic module assembly optionally in a chamber at evacuating conditions;
   (iii) a pressing step to build and keep pressure on the photovoltaic module assembly at the heated conditions for the lamination of the assembly to occur; and
   (iv) a recovering step to cool and remove the obtained photovoltaic module for later use.

As the preferable embodiment of the invention, the process is for producing a photovoltaic (PV) module of the invention, as defined above, below or in claims, comprising, in the given order, a protective front layer element, preferably a glass layer element, a front encapsulation layer element, a photovoltaic element, a rear encapsulation layer element and a protective back layer element, preferably a glass layer element, wherein the front encapsulation layer element and the rear encapsulation layer element are the layer (L) comprising a polymer composition (C) of the invention which comprises
a polymer of ethylene (a) as defined above or in claims;
silane group(s) containing units (b);
   and wherein the polymer composition (C) has a melt flow rate, MFR₂, of less than 20 g/10 min (according to ISO 1133 at 190° C. and at a load of 2.16 kg); and wherein the process comprises the steps of:
   (i) an assembling step to arrange the protective front layer element, the front encapsulation layer element, the photovoltaic element, the rear encapsulation layer element and the protective back layer element, in given order, to form of a photovoltaic module assembly;
   (ii) a heating step to heat up the photovoltaic module assembly optionally in a chamber at evacuating conditions;
   (iii) a pressing step to build and keep pressure on the photovoltaic module assembly at the heated conditions for the lamination of the assembly to occur; and
   (iv) a recovering step to cool and remove the obtained photovoltaic module for later use. The lamination process is carried out in laminator equipment which can be e.g. any conventional laminator which is suitable for the multilaminate to be laminated. The choice of the laminator is within the skills of a skilled person. Typically, the laminator comprises a chamber wherein the heating, optional, and preferable, evacuation, pressing and recovering (including cooling) steps (ii)-(iv) take place.

In a preferable lamination process of the invention:
the pressing step (iii) is started when at least one of the front encapsulation or rear encapsulation layer element(s) reaches a temperature which is at least 3 to 10° C. higher than the melting temperature of the polymer of ethylene (a) present in said front and/or encapsulation layer element; and
the total duration of the pressing step (iii) is up to 15 minutes.

The process of the invention can shorten the lamination process markedly.

The duration of the heating step (ii) is preferably up to 10 minutes, preferably 3 to 7 minutes. The heating step (ii) can be and is typically done step-wise.

Pressing step (iii) is preferably started when the at least one layer element (L) reaches a temperature which is 3 to 10° C. higher than the melting temperature of the polymer (a), preferably of the polymer (a1) or (a2), of said layer element (L).

The pressing step (iii) is preferably started when the at least one layer element (L) reaches a temperature of at least of 85° C., suitably to 85 to 150° C., suitably to 85 to 148° C., suitably 85 to 140° C., preferably 90 to 130° C., preferably 90 to 120° C., preferably 90 to 115° C., preferably 90 to 110° C., preferably 90 to 108° C.

At the pressing step (iii), the duration of the pressure build-up is preferably up to 5 minutes, preferably 0.5 to 3 minutes. The pressure built up to the desired level during pressing step can be done either in one step or can be done in multiple steps.

At the pressing step (iii), the duration of holding the pressure is preferably up to 10 minutes, preferably 3.0 to 10 minutes.

The total duration of the pressing step (iii) is preferably from 2 to 10 minutes.

The total duration of the heating step (ii) and pressing step (iii) is preferably up to 25, preferably from 2 to 20, minutes.

The pressure used in the pressing step (iii) is preferably up to 1000 mbar, preferably 500 to 900 mbar.

### Determination Methods

Unless otherwise stated in the description or in the experimental part, the following methods were used for the property determinations of the polymer composition, polar polymer and/or any sample preparations thereof as specified in the text or experimental part.

### Determination of the Depth (%) of the Recesses of a Layer Element (L)

The depth (%) of the recesses means herein the ratio of the deepest recess(s) to the thickness of the thickest part of the layer (L) along the length of 1 mm cross-section of the layer (L) element. FIGS. 1 to 3 illustrate the measurement of the depth (%) of the recesses. In FIGS. 1 to 3, (x) denotes the depth (μm) of the deepest recess(s) and (y) the thickness (μm) of the thickest part of the layer (L) along the length of 1 mm cross-section of the layer element (L). The (x) and (y) are measured using microscopy and a magnification by a factor of 100.

### Melt Flow Rate

The melt flow rate (MFR) is determined according to ISO 1133 and is indicated in g/10 min. The MFR is an indication of the flowability, and hence the processability, of the polymer. The higher the melt flow rate, the lower the viscosity of the polymer. The MFR is determined at 190° C. for polyethylene. MFR may be determined at different loadings such as 2.16 kg (MFR₂) or 5 kg (MFR₅).

### Density

Low density polyethylene (LDPE): The density of the polymer was measured according to ISO 1183-2. The sample preparation was executed according to ISO 1872-2 Table 3 Q (compression moulding).

### Comonomer Contents:

### The Content (Wt % and Mol %) of Polar Comonomer Present in the Polymer and the Content (Wt % and Mol %) of Silane Group(s) Containing Units (Preferably Comonomer) Present in the Polymer Composition (Preferably in the Polymer):

Quantitative nuclear-magnetic resonance (NMR) spectroscopy was used to quantify the comonomer content of the polymer composition or polymer as given above or below in the context.

Quantitative ¹H NMR spectra recorded in the solution-state using a Bruker Advance III 400 NMR spectrometer operating at 400.15 MHz. All spectra were recorded using a standard broad-band inverse 5 mm probehead at 100° C. using nitrogen gas for all pneumatics. Approximately 200 mg of material was dissolved in 1,2-tetrachloroethane-d₂ (TCE-d₂) using ditertiarybutylhydroxytoluen (BHT) (CAS 128-37-0) as stabiliser. Standard single-pulse excitation was employed utilising a 30 degree pulse, a relaxation delay of 3 s and no sample rotation. A total of 16 transients were acquired per spectra using 2 dummy scans. A total of 32 k data points were collected per FID with a dwell time of 60 s, which corresponded to a spectral window of approx. 20 ppm. The FID was then zero filled to 64 k data points and an exponential window function applied with 0.3 Hz line-broadening. This setup was chosen primarily for the ability to resolve the quantitative signals resulting from methylacrylate and vinyltrimethylsiloxane copolymerisation when present in the same polymer.

Quantitative ¹H NMR spectra were processed, integrated and quantitative properties determined using custom spectral analysis automation programs. All chemical shifts were internally referenced to the residual protonated solvent signal at 5.95 ppm.

When present characteristic signals resulting from the incorporation of vinylacytate (VA), methyl acrylate (MA), butyl acrylate (BA) and vinyltrimethylsiloxane (VTMS), in various comonomer sequences, were observed (Randell89). All comonomer contents calculated with respect to all other monomers present in the polymer.

The vinylacytate (VA) incorporation was quantified using the integral of the signal at 4.84 ppm assigned to the *VA sites, accounting for the number of reporting nuclei per comonomer and correcting for the overlap of the OH protons from BHT when present:

VA=(I_{*VA}−(I_{ArBHT})/2)/1

The methylacrylate (MA) incorporation was quantified using the integral of the signal at 3.65 ppm assigned to the 1MA sites, accounting for the number of reporting nuclei per comonomer:

MA=I_{1MA}/3

The butylacrylate (BA) incorporation was quantified using the integral of the signal at 4.08 ppm assigned to the 4BA sites, accounting for the number of reporting nuclei per comonomer:

BA=I_{4BA}/2

The vinyltrimethylsiloxane incorporation was quantified using the integral of the signal at 3.56 ppm assigned to the 1VTMS sites, accounting for the number of reporting nuclei per comonomer:

VTMS=I_{1VIMS}/9

Characteristic signals resulting from the additional use of BHT as stabiliser, were observed. The BHT content was quantified using the integral of the signal at 6.93 ppm assigned to the ArBHT sites, accounting for the number of reporting nuclei per molecule:

BHT=I_{ArBHT}/2

The ethylene comonomer content was quantified using the integral of the bulk aliphatic (bulk) signal between 0.00-3.00 ppm. This integral may include the IVA (3) and αVA (2) sites from isolated vinylacetate incorporation, *MA and αMA sites from isolated methylacrylate incorporation, 1BA (3), 2BA (2), 3BA (2), *BA (1) and αBA (2) sites from isolated butylacrylate incorporation, the *VTMS and αVTMS sites from isolated vinylsilane incorporation and the aliphatic sites from BHT as well as the sites from polyethylene sequences. The total ethylene comonomer content was calculated based on the bulk integral and compensating for the observed comonomer sequences and BHT:

E=(¼)*[I_{bulk}−5*VA−3*MA−10*BA−3*VTMS−21*BHT]

It should be noted that half of the a signals in the bulk signal represent ethylene and not comonomer and that an insignificant error is introduced due to the inability to compensate for the two saturated chain ends (S) without associated branch sites.

The total mole fractions of a given monomer (M) in the polymer was calculated as:

fM=M/(E+VA+MA+BA+VTMS)

The total comonomer incorporation of a given monomer (M) in mole percent was calculated from the mole fractions in the standard manner:

M [mol %]=100*fM

The total comonomer incorporation of a given monomer (M) in weight percent was calculated from the mole fractions and molecular weight of the monomer (MW) in the standard manner:

M [wt %]=100*(fM*MW)/((fVA*86.09)+(fMA*86.09)+(fBA*128.17)+(fVTMS*148.23)+((1−fVA−fMA−fBA−fVTMS)*28.05))

randall89: J. Randall, Macromol. Sci., Rev. Macromol. Chem. Phys. 1989, C29, 201.

If characteristic signals from other specific chemical species are observed the logic of quantification and/or compensation can be extended in a similar manor to that used for the specifically described chemical species. That is, identification of characteristic signals, quantification by integration of a specific signal or signals, scaling for the number of reported nuclei and compensation in the bulk integral and related calculations. Although this process is specific to the specific chemical species in question the approach is based on the basic principles of quantitative NMR spectroscopy of polymers and thus can be implemented by a person skilled in the art as needed.

### Adhesion Test:

The adhesion test is performed on laminated strips. The encapsulation film and a backsheet are peeled of in a tensile testing equipment while measuring the force required for the peeling.

A laminate consisting of glass layer (3.2 mm thick structured solar glass), 2 encapsulant layer elements (test layer elements) and backsheet layer (DYMAT® PYE Standard backsheet (PET/PET/Primer), supplied by Covme, total thickness of 300 micron) is first laminated with sample structure from bottom to top: glass-test layer element-test layer element-backsheet. Both test layer elements as encapsulant layers were the same and the embossed side (pattern of recesses) of first test layer element was facing the glass layer while the embossed side (patter of recesses) of the second test layer element was facing the backsheet layer. Between the glass and the first encapsulat film a small sheet of Teflon is inserted at one of the ends, this will generate a small part of the encapsulants and backsheet that is not adhered to the glass. This part will be used as the anchoring point for the tensile testing device.

The laminate is then cut along the laminate to form a 15 mm wide strip, the cut goes through the backsheet and the encapsulant films all the way down to the glass surface.

The laminate is mounted in the tensile testing equipment and the clamp of the tensile testing device is attached to the end of the strip.

The pulling angle is 90° in relation to the laminate and the pulling speed is 14 mm/min.

The pulling force is measured as the average during 50 mm of peeling starting 25 mm into the strip.

The average force over the 50 mm is divided by the width of the strip (15 mm) and presented as adhesion strength (N/cm).

### Rheological Properties:

### Dynamic Shear Measurements (Frequency Sweep Measurements)

The characterisation of melt of polymer composition or polymer as given above or below in the context by dynamic shear measurements complies with ISO standards 6721-1 and 6721-10. The measurements were performed on an Anton Paar MCR501 stress controlled rotational rheometer, equipped with a 25 mm parallel plate geometry. Measurements were undertaken on compression moulded plates, using nitrogen atmosphere and setting a strain within the linear viscoelastic regime. The oscillatory shear tests were done at 190° C. applying a frequency range between 0.01 and 600 rad/s and setting a gap of 1.3 mm.

In a dynamic shear experiment the probe is subjected to a homogeneous deformation at a sinusoidal varying shear strain or shear stress (strain and stress controlled mode, respectively). On a controlled strain experiment, the probe is subjected to a sinusoidal strain that can be expressed by

γ(t)=γ₀ sin(ωt) (1)

If the applied strain is within the linear viscoelastic regime, the resulting sinusoidal stress response can be given by

σ(t)=σ₀ sin(ωt+δ) (2)

where
σ₀ and γ₀ are the stress and strain amplitudes, respectively
ω is the angular frequency
δ is the phase shift (loss angle between applied strain and stress response)
t is the time

Dynamic test results are typically expressed by means of several different rheological functions, namely the shear storage modulus G′, the shear loss modulus, G″, the complex shear modulus, G*, the complex shear viscosity, η*, the dynamic shear viscosity, η′, the out-of-phase component of the complex shear viscosity η″ and the loss tangent, tan δ which can be expressed as follows:

$$\begin{matrix}{G}^{′} = \frac{{σ}_{0}}{{γ}_{0}} cos δ [ Pa ] & ( 3 ) \\ {G}^{″} = \frac{{σ}_{0}}{{γ}_{0}} sin δ [ Pa ] & ( 4 ) \\ {G}^{*} = {G}^{′} + {iG}^{″} [ Pa ] & ( 5 ) \\ {η}^{*} = {η}^{′} - i {η}^{″} [ Pa \cdot s ] & ( 6 ) \\ {η}^{′} = \frac{{G}^{″}}{ω} [ Pa \cdot s ] & ( 7 ) \\ {η}^{″} = \frac{{G}^{′}}{ω} [ Pa \cdot s ] & ( 8 )\end{matrix}$$

Besides the above mentioned rheological functions one can also determine other rheological parameters such as the so-called elasticity index EI(x). The elasticity index EI(x) is the value of the storage modulus, G′ determined for a value of the loss modulus, G″ of x kPa and can be described by equation (9).

EI(x)=G′ for (G″=x kPa) [Pa] (9)

For example, the EI(5 kPa) is the defined by the value of the storage modulus G′, determined for a value of G″ equal to 5 kPa.

Shear Thinning Index (SHI_{0.05/300}) is defined as a ratio of two viscosities measured at frequencies 0.05 rad/s and 300 rad/s, μ_{0.05}/μ₃₀₀.

### REFERENCES

[1] Rheological characterization of polyethylene fractions” Heino, E. L., Lehtinen, A., Tanner J., Seppili, J., Neste Oy, Porvoo, Finland, Theor. Appl. Rheol., Proc. Int. Congr. Rheol, 11th (1992), 1, 360-362
[2] The influence of molecular structure on some rheological properties of polyethylene”, Heino, E. L., Borealis Polymers Oy, Porvoo, Finland, Annual Transactions of the Nordic Rheology Society, 1995.).
[3] Definition of terms relating to the non-ultimate mechanical properties of polymers, Pure & Appl. Chem., Vol. 70, No. 3, pp. 701-754, 1998.
   Melting Temperature (Tₘ), Crystallization Temperature (Tₑᵣ), and Degree of Crystallinity

The melting temperature Tₘ of the used polymers was measured in accordance with ASTM D3418. Tₘ and Tₑᵣ were measured with Mettler TA820 differential scanning calorimetry (DSC) on 3±0.5 mg samples. Both crystallization and melting curves were obtained during 10° C./min cooling and heating scans between −10 to 200° C. Melting and crystallization temperatures were taken as the peaks of endotherms and exotherms. The degree of crystallinity was calculated by comparison with heat of fusion of a perfectly crystalline polymer of the same polymer type, e.g. for polyethylene, 290 J/g.

### EXPERIMENTAL PART

Polymerisation of Polymer (a) (Inv. Ex. 1 and Inv. Ex. 2) (Copolymer of Ethylene with Methyl Acrylate Comonomer and with Vinyl Trimethoxysilane Comonomer)

Inventive polymer (a) was produced in a commercial high pressure tubular reactor at a pressure 2500-3000 bar and max temperature 250-300° C. using conventional peroxide initiator. Ethylene monomer, methyl acrylate (MA) polar comonomer and vinyl trimethoxy silane (VTMS) comonomer (silane group(s) containing comonomer (b)) were added to the reactor system in a conventional manner. CTA was used to regulate MFR as well known for a skilled person. After having the information of the property balance desired for the inventive final polymer (a), the skilled person can control the process to obtain the inventive polymer (a).

The amount of the vinyl trimethoxy silane units, VTMS, (=silane group(s) containing units), the amount of MA and MFR₂ are given in the table 1.

The properties in below tables were measured from the polymer (a) as obtained from the reactor or from a layer sample as indicated below.

TABLE 1
Product properties of Inventive Examples

| Properties of the | | |
|---|---|---|
| polymer obtained | Test polymer (a) | |
| from the reactor | Inv. Ex. 1 | Inv. Ex. 2 |
| MFR_{2, 16}, g/10 min | 2.0 | 16 |
| acrylate content, | MA 8.1 | MA 8.0 |
| mol % | | |
| Melt Temperature, | 92 | 89 |
| ° C. | | |
| VTMS content, | 0.41 | 0.23 |
| mol % | | |
| Density, kg/m³ | 948 | 945 |
| SHI (0.05/300), | 70 | |
| 150° C. | | |

In above table 1 MA denotes the content of Methyl Acrylate comonomer present in the polymer and, respectively, VTMS content denotes the content of vinyl trimethoxy silane comonomer present in the polymer.

The polymer of Inv. ex. 1 and Inv. ex. 2 were used below to prepare inventive and comparative layer elements.

### Preparation of the Embossed Thermoplastic Film

The inventive and comparative layer element samples were prepared by film extrusion process to form first a monolayer film. The thickness of the film samples before embossing (using embossing rolls) was 450 μm. Subsequently to film formation the pattern of recesses was provided by embossing on one side of the film using a conventional calender, whereby one of the calendars thereof was embossed to transfer a pattern of recesses onto one surface of the test layer element by passing the semimolten layer element through a nip gap. Different settings were use for each sample to result in varying depths of the recesses as evident for a skilled person.

Microscopy photos (in two different magnifications, scales 2 mm and 200 m) in FIGS. 4 to 9 show the inventive and comparative layer element samples having varying depth (%) of recesses on one surface of each sample before lamination.

The obtained layer elements were laminated on a glass layer and backsheet layer as described above for Adhesion Test under “Determination methods”. The Adhesion was measured from the surface (with pattern of recesses) of the layer element sample which was facing the surface of the glass layer.

TABLE 2
Depth (%) of the recesses as well as adhesion test results
of the inv. and comp. layer element samples

| | Inv. layer | Inv. layer | Inv. layer | Com- |
|---|---|---|---|---|
| | (L)-A of | (L)-B of | (L)-C of | parative |
| | Inv. ex. 2 | Inv. ex. 1 | Inv. ex. 1 | layer |
| depth of the recesses (%) | 10% of | 20% of | 37% of | 80% of the |
| | the film | the film | the film | film |
| | thickness | thickness | thickness | thickness |
| Adhesion of the layer | >150 | >150 | >150 | <80 |
| element sample to glass | | | | |
| element [N/cm] | | | | |
| (lamination 2 + 4 minutes, | | | | |
| 145° C., 800 mbar) | | | | |

Also the adhesion of the layer element sample to backsheet was measured. Similarly, the adhesion of Inv. Layer (L)-A, Inv. layer (L)-B and Inv. layer (L)-B were clearly better (higher) compared to the Comparative layer.

### Lamination Examples

### Materials of the PV Module (60 Cells Solar Module) Elements:

Glass layer element (=protective front layer element): Solatex solar glass, supplied by AGC, length: 1632 mm and width: 986 mm, total thickness of 3.2 mm Front and rear encapsulation layer element: Both consisted of Inv. layer element (L)-B, had same width and length dimensions as the glass layer element (the protective front layer element) and each had independently the total thickness of 0.45 mm before embossing as described above.

PV Cell element: 60 monocrystalline solar cells, cell dimension 156*156 mm, supplied by Tsec Taiwan, 2 buss bars, total thickness of 200 micron.

Backsheet element (=protective back layer element): DYMAT® PYE Standard backsheet (PET/PET/Primer), supplied by Covme, total thickness of 300 micron.

### Preparation of PV Module (60 Cells Solar Module) Assembly for the Lamination:

Five PV module assembly samples were prepared as follows. The front protective glass layer element (Solatex AGC) was cleaned with isopropanol before putting the first encapsulation layer element on the solar glass. The glass layer element has the following dimensions: 1632 mm×986×3.2 mm (b*l*d). The front encapsulation layer element was cut in the same dimension as the solar glass layer element and the surface with the pattern of recesses of the Inv. layer (L)-element-B was arranged in direct contact with the surface of the glass layer element. The solar cells as PV cell element have been automatically stringed by 10 cells in series with a distance between the cells of 1.5 mm. After the front encapsulation element was put on the front protective glass layer element, then the solar cells were put on the front encapsulant element with 6 rows of each 10 cells with a distance between the rows of ±2.5 mm to have a total of 60 cells in the solar module as a standard module. Then the ends of the solar cells are soldered together to have a fully integrated connection as well known by the PV module producers. Further the rear encapsulation element was put on the obtained PV cell element so that the surface with the pattern of recesses of the Inv. layer (L)-element-B was arranged in direct contact with the surface of the PV cell element, and then the Coveme DYMAT PYE backsheet element which had a slightly bigger dimension in length and width as the front protective glass plate (±5 mm) was put on said the rear encapsulation element. The obtained PV module assembly samples were then subjected to a lamination process test as described below.

### Lamination Process of the 60 Cells Solar Modules:

### Laminator:

ICOLAM 25/15, supplied by Meier Vakuumtechnik GmbH. Each PV module assembly sample was laminated in a Meier ICOLAM 25/15 laminator from Meier Vakuumtechnik GmbH with a laminator temperature setting of 145° C. and pressure setting of 800 mbar. The lamination conditions for the sample is given in table 2.

TABLE 2
Lamination process with duration of the steps of the process

| | | | Holding the | |
|---|---|---|---|---|
| | | Encapsulant | pressure | |
| | Heating step (ii) | temperature | substep of | Total time of |
| Lamination | with Evacuation | when pressing | pressing step | steps (ii) + |
| Test no. | (min) | starts (° C.) | (iii) (min) | (iii) (min) |
| Test 1 | 2.0 | 105 | 4.0 | 6.0 |

1: A layer element (L) comprising an ethylene polymer composition (C) which comprises:
a polymer of ethylene (a);
silane group(s) containing units (b); and wherein
the ethylene polymer composition (C) has an MFR₂ of less than 20 g/10 min when determined according to ISO 1133 (at 190° C. and at a load of 2.16 kg); and wherein
at least one of the layer surfaces of the layer element (L) is provided with a pattern of recesses.

2: The layer element (L) according to claim 1,
wherein the depth (%) of the recesses of the at least one layer surface is below 70% T and at least 5%, of the thickness of the layer element (L), when measured in the cross-section of a 1 mm long layer element (L).

3: The layer element (L) according to claim 1, wherein the pattern of recesses of the at least one layer surface are embossed.

4: The layer element (L) according to claim 1, wherein the composition (C), has a melt flow rate, MFR₂, of preferably less than 15 g/10 min (according to ISO 1133 at 190° C. and at a load of 2.16 kg).

5: The layer element (L) according to claim 1, wherein the composition (C), has a melting temperature of 120° C. or less when measured according to ASTM D3418.

6: The layer element (L) according to claim 1, wherein polymer of ethylene (a) comprises one of:
(a1) a polymer of ethylene which optionally contains one or more comonomer(s) other than a polar comonomer of polymer (a2) and which bears functional groups containing units;
(a2) a polymer of ethylene containing one or more polar comonomer(s) selected from (C₁-C₆)-alkyl acrylate or (C₁-C₆)-alkyl (C₁-C₆)-alkylacrylate comonomer(s), and optionally bears functional group(s) containing units other than said polar comonomer; or
(a3) a polymer of ethylene containing one or more alpha-olefin comonomer selected from (C₁-C₁₀)-alpha-olefin comonomer; and optionally bears functional group(s) containing units; and
silane group(s) containing units (b).

7: The layer element (L) according to claim 1, wherein the composition (C) comprises:
a polymer of ethylene (a) which is selected from:
(a1) a polymer of ethylene which optionally contains one or more comonomer(s) other than the polar comonomer of polymer (a2) and which bears functional groups containing units other than said optional comonomer(s); or
(a2) a polymer of ethylene containing one or more polar comonomer(s) selected from (C₁-C₆)-alkyl acrylate or (C₁-C₆)-alkyl (C₁-C₆)-alkylacrylate comonomer(s), and optionally bears functional group(s) containing units other than said polar comonomer; and
silane group(s) containing units (b);
the composition (C) comprises;
a polymer of ethylene (a) which is the polymer of ethylene (a2) containing one or more polar comonomer(s) selected from (C₁-C₆)-alkyl acrylate or (C₁-C₆)-alkyl (C₁-C₆)-alkylacrylate and bears functional group(s) containing units other than said polar comonomer; and
silane group(s) containing units (b); or
the composition (C) comprises a polymer of ethylene (a) which is the polymer of ethylene (a2) containing one or more polar comonomer(s) selected from (C₁-C₆)-alkyl acrylate or (C₁-C₆)-alkyl (C₁-C₆)-alkylacrylate comonomer(s), and bears the silane group(s) containing units (b) as the functional group(s) containing units.

8: The layer element (L) according to claim 1, wherein the polymer of ethylene (a) bears functional groups containing units which are silane group(s) containing units (b) as a copolymerized comonomer or as a grafted compound, and which silane group(s) containing units (b) is a hydrolysable unsaturated silane compound represented by the formula:
R1SiR2Y_{3-q} (I)
wherein, R1 is an ethylenically unsaturated hydrocarbyl, hydrocarbyloxy or (meth)acryloxy hydrocarbyl group,
each R2 is independently an aliphatic saturated hydrocarbyl group,
Y which may be the same or different, is a hydrolysable organic group, and
q is 0, 1 or 2, the amount of the silane group(s) containing units (b) present in the polymer (a), is from 0.01 to 1.00 mol %.

9. (canceled)

10: An article comprising a layer element (L) according to claim 1.

11: The article according to claim 10, which comprises a multilayer laminate.

12: The article according to claim 10, which is a photovoltaic (PV) module comprising, in the given order, a protective front layer element, a front encapsulation layer element, a photovoltaic element, a rear encapsulation layer element and a protective back layer element, wherein the front encapsulation layer element and/or the rear encapsulation layer element comprising:
a polymer of ethylene (a);
silane group(s) containing units (b);
and wherein the polymer composition (C) has a melt flow rate, MFR₂, of less than 20 g/10 min (according to ISO 1133 at 190° C. and at a load of 2.16 kg).

13. (canceled)

14: A process for producing an article according to claim 10, by lamination comprising,
(i) an assembling step to arrange the layer element (L) with at least one further layer element to form of a multilayer assembly, wherein the at least one surface of layer (L) with the pattern of recesses is in contact with one of the outer surfaces of said further layer element of the assembly;
(ii) a heating step to heat up the formed multilayer assembly optionally in a chamber at evacuating conditions;
(iii) a pressing step to build and keep pressure on the multilayer assembly at the heated conditions for the lamination of the assembly to occur; and
(iv) a recovering step to cool and remove the obtained article comprising the multilayer laminate.

15: The process according to claim 14, wherein the article is a photovoltaic (PV) module which includes, in the given order, a protective front layer element, a front encapsulation layer element, a photovoltaic element, a rear encapsulation layer element and a protective back layer element, wherein the front encapsulation layer element and/or the rear encapsulation layer element, is the layer (L) comprising a polymer composition (C)
a polymer of ethylene (a);
silane group(s) containing units (b);
and wherein the polymer composition (C) has a melt flow rate, MFR₂, of less than 20 g/10 min (according to ISO 1133 at 190° C. and at a load of 2.16 kg);
and wherein the process comprises the steps of:
(i) an assembling step to arrange the protective front layer element, the front encapsulation layer element, the photovoltaic element, the rear encapsulation layer element and the protective back layer element, in given order, to form of a photovoltaic module assembly;
(ii) a heating step to heat up the photovoltaic module assembly optionally in a chamber at evacuating conditions;
(iii) a pressing step to build and keep pressure on the photovoltaic module assembly at the heated conditions for the lamination of the assembly to occur; and
(iv) a recovering step to cool and remove the obtained photovoltaic module for later use.

16. (canceled)
